(19) United States
(12) Patent Application Publication
(10) Pub. No.: US 2007/0070758 A1
(43) Pub. Date: Mar. 29, 2007

(54) SEMICONDUCTOR MEMORY WITH SENSE AMPLIFIER AND SWITCH

(75) Inventors: Tobias Graf, Neubiberg (DE); Joerg Kliewer, Muenchen (DE); Manfred Proell, Dorfen (DE); Stephan Schroeder, Muenchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/534,400

(22) Filed: Sep. 22, 2006

(30) Foreign Application Priority Data
Sep. 22, 2005 (DE) 10 2005 045 311.2

(51) Int. Cl. G11C 7/02

(52) U.S. Cl. 365/208

(57) ABSTRACT

A method for operating a semiconductor memory and to a semiconductor memory with at least one sense amplifier and device for switching the sense amplifier to or off at least one line is disclosed. The means is, during the switching of the sense amplifier to the line, placed in a conductive state for a differently long time and/or differently strongly, depending on the respective operating mode of the semiconductor memory.

### CROSS-REFERENCE TO RELATED APPLICATIONS

This Utility Patent Application claims priority to German Patent Application No. DE 10 2005 045 311.2 filed on Sep. 22, 2005, which is incorporated herein by reference.

### BACKGROUND

The invention provides a semiconductor memory, in particular a DRAM (Dynamic Random Access Memory), and a method for operating a semiconductor memory.

The memory field of a DRAM consists of rows (or a plurality of word lines, respectively) and columns (or a plurality of bit lines, respectively).

In DRAMs, the memory cells, which consist substantially of capacitors, are connected to bit lines so as to transmit a data value to be read out from a memory cell or to be read into a memory cell. During the reading out of memory cell (“read procedure”), an access transistor connected with the capacitor of a memory cell is connected through by the activation of a word line, and the charge state stored in the capacitor is applied to the bit line. In so doing, the capacitor charge is divided to the capacitance of the cell and of the bit line. Corresponding to the ratio of these two capacitances (transfer ratio), a more or less strong deflection of the bit line voltage will occur.

The weak signal coming from the capacitor will be amplified by a sense amplifier (e.g., by a primary sense amplifier—SA). The sense amplifier includes complementary signal inputs. The bit lines connected with these signal inputs are referred to as bit line and complementary bit line.

In today's DRAMS, the sense amplifiers are, as a rule, used in a divided manner so as to save chip space. A sense amplifier is used both for the reading out of memory cells arranged at the left and at the right along a bit line adjacent to the sense amplifier (i.e. for the reading out of memory cells that are arranged in a cell field block of the memory field positioned both at the left and at the right of the sense amplifier).

A plurality of sense amplifiers are arranged side by side in a corresponding sense amplifier strip that is positioned between two cell field blocks assigned to the sense amplifiers.

Prior to the reading out of the memory cells, the corresponding bit line sections, i.e. the corresponding sections of the non-complementary bit line and of the complementary bit line, are precharged, by precharge/equalize circuits that are connected with the bit lines, to an equal potential that corresponds to half the voltage of a bit line in the H-state (=VBLH/2). Thus it is ensured that, prior to the reading out, no differences occur between the potential of a section of the bit line and the section of the complementary bit line assigned thereto, which might overlap or distort the small amount of charge transmitted to the bit line by the capacitor of a memory cell during reading out. Directly before the reading out of the memory cells, the precharge/equalize circuits that are adapted to be connected with the bit line sections, the memory cell to be read out, and the sense amplifier, are switched off.

Known DRAMs moreover include isolation transistors that serve to decouple the sense amplifier during the reading out of the cells from that side that is not to be read out (i.e. to decouple either the cell field block positioned at the left or that positioned at the right of the sense amplifier).

The actual reading out of the memory cell is initiated shortly thereafter in that word line signals present at a corresponding word line connect through the access transistors that are connected with the memory capacitors.

Each word line is assigned to a particular cell field block of the above-mentioned memory field blocks and provides on its activation for the evaluation of all the bit lines of the cell field block assigned to the word line by means of the corresponding sense amplifiers.

By means of a bit line address forwarded to the DRAM, one each of the sense amplifiers positioned in the corresponding sense amplifier strip is selected in that a bit line switch (CSL gate) assigned to the selected sense amplifier is placed in a conductive, i.e. opened state.

Then, the potential difference amplified by the selected sense amplifier and present at the respective bit line sections is transmitted via the bit line switch (CSL gate) and corresponding LDQ and MDQ lines to a further sense amplifier (e.g., a secondary sense amplifier—SSA).

This sense amplifier evaluates the received signal and transmits a—correspondingly amplified—signal to corresponding connections (DQ) of the DRAM.

Vice versa, during the reading or writing, respectively, of data into the DRAM (“write procedure”), a signal present at corresponding connections (DQ) of the DRAM is correspondingly amplified by the above-mentioned further sense amplifier (secondary sense amplifier—SSA) and transmitted, via the MDQ and LDQ lines, to a sense amplifier (primary sense amplifier—SA) selected by a corresponding bit line address and positioned in one of the above-mentioned sense amplifier strips.

The selection of the sense amplifier is again performed in that the bit line switch (CSL gate) assigned to the selected sense amplifier is placed in a conductive, i.e. opened state.

The opened bit line switch (CSL gate) switches the signal amplified by the SSA to the selected sense amplifier (primary sense amplifier—SA) that has already been amplified with the predecessor data of the cell; the possibly necessary overwriting of the predecessor data requires that the bit line switch (CSL gate) assigned to the selected sense amplifier is in a state that is as lowly resistive as possible.

On the other hand, in the above-described—inverse—case of the reading out of data (“read procedure”) it must be ensured that the LDQ and MDQ lines that are on a predefined potential do not influence the respectively selected sense amplifier to an extent that the original cell information tilts.

For this case, the opened bit line switch (CSL gate) assigned to the respectively selected sense amplifier (primary sense amplifier—SA) must not be of too low resistance.

For these and other reasons, there is a need for the present invention.

### SUMMARY

One or more embodiments provide a method for operating a semiconductor memory and a semiconductor memory with at least one sense amplifier and device for switching said sense amplifier to or off at least one line. In one embodiment, the device is, during the switching of the sense amplifier to the line, placed in a conductive state for a differently long time and/or differently strongly, depending on the respective operating mode of the semiconductor memory.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a section from a DRAM which is relevant for the invention;

FIG. 2 illustrates a signal diagram of different signals that are relevant during the reading in and the reading out of data into or from a memory cell of the DRAM illustrated in FIG. 1, in particular of a control signal CL fed to a bit line switch during a write or a read procedure;

FIG. 3 illustrates a signal diagram of different signals that are relevant during the reading in and the reading out of data into or from a memory cell of the DRAM illustrated in FIG. 1, in particular of a control signal CL fed to a bit line switch during a write or a read procedure in accordance with an alternative embodiment;

FIG. 4 illustrates a schematic detail representation of a first exemplary design of a bit line decoder output stage that can be used with the DRAM according to FIG. 1; and

FIG. 5 illustrates a schematic detail representation of a second, alternative, exemplary design of a bit line decoder output stage that can be used with the DRAM according to FIG. 1.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a semiconductor memory that is improved vis-à-vis conventional semiconductor memories, and an improved method for operating a semiconductor memory, in particular a semiconductor memory that is better adapted to the respective operating mode, e.g., “read” or “write”, than conventional semiconductor memories.

In accordance with one embodiment of the invention there is provided a semiconductor memory having at least one sense amplifier and a device, in particular a bit line switch for switching the sense amplifier to or off at least one line, wherein the device, in particular the bit line switch, is, during the switching of the sense amplifier to the line, placed in a conductive state for a differently long time and/or differently strongly, depending on the respective operating mode of the semiconductor memory.

The operating mode may, for instance, be a read mode, and/or a write mode, etc.

The device, in particular the bit line switch, includes at least one transistor that is placed, from a non-conductive state, depending on the respective operating mode of the semiconductor memory, to a conductive state for a differently long time and/or differently strongly, and then back to the non-conductive state.

In one embodiment, the sense amplifier is, during the switching of the sense amplifier to the line, connected with a further sense amplifier, in particular with a secondary sense amplifier.

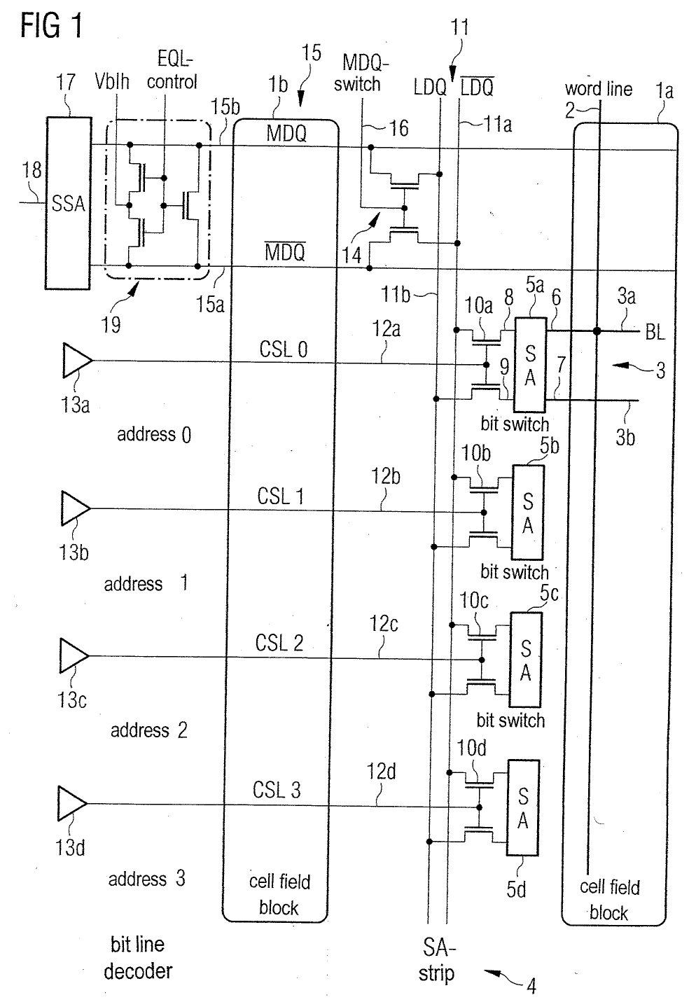

In the section of a DRAM illustrated in FIG. 1, several cell field blocks 1a, 1b are illustrated, in each of which a plurality of memory cells (not illustrated) are arranged—positioned in a plurality of rows and columns.

Through each cell field block 1a, 1b there run a plurality of word lines 2 parallel to each other, and—also parallel to each other and perpendicularly to the word lines 2—a plurality of bit lines 3a, 3b.

As results from FIG. 1, a sense amplifier strip 4 (SA strip) each is positioned between every two cell field blocks 1a, 1b, the sense amplifier strip 4 having a plurality of sense amplifiers 5a, 5b, 5c, 5d (here: a plurality of primary sense amplifiers—SA) positioned side by side in an array.

As will be explained in more detail in the following, the memory cells, which substantially consist of capacitors, can each be connected to corresponding bit lines 3a, 3b to transmit a data value to be read out form a memory cell or a data value to be read into a memory cell. During the reading out of a memory cell (“read procedure” (READ)), an access transistor (not illustrated here) that is connected with the capacitor of a memory cell is connected through by the activation of a corresponding word line 2, and the charge state stored in the capacitor is applied to a corresponding bit line 3a, 3b.

Then, the weak signal coming from the capacitor is amplified by one of the above-mentioned sense amplifiers 5a, 5b, 5c, 5d.

As results from FIG. 1 (illustrated there by means of the sense amplifier 5a), each of the sense amplifiers 5a, 5b, 5c, 5d includes two respective complementary signal inputs/outputs 6, 7, wherein a respective first one of the signal inputs/outputs 6 is connected with a first bit line 3a of a bit line pair 3, and a respective second one of the signal inputs/outputs 7 with a second, complementary bit line 3b of the bit line pair 3.

The sense amplifiers 5a, 5b, 5c, 5d are “divided” sense amplifiers: The sense amplifiers 5a, 5b, 5c, 5d are used during the reading out of memory cells arranged in the cell field blocks 1a, 1b both positioned at the left and at the right of the sense amplifiers 5a, 5b, 5c, 5d.

Prior to the reading out of the memory cells, the corresponding bit line sections, i.e. the corresponding sections of the non-complementary bit line 3a and of the complementary bit line 3b, are precharged, by a (not illustrated) precharge/equalize circuit that is connected with the bit lines 3a, 3b, to an equal potential that corresponds to half the voltage of a bit line in the H-state (=VBLH/2). Thus it is ensured that, prior to the reading out, no differences between the potential of a section of the bit line 3a and the section of the complementary bit line 3b assigned thereto occur, which might overlap or distort the small amount of charge transmitted to the bit line by the capacitor of a memory cell during reading out. Directly before the reading out of the memory cells, the precharge/equalize circuit that is adapted to be connected with the bit line sections, the memory cell to be read out, and the sense amplifier 5a, 5b, 5c, 5d, is switched off.

Between the sense amplifiers 5a, 5b, 5c, 5d (or the above-mentioned sense amplifier inputs/outputs 6, 7, respectively) and the bit lines 3a, 3b, corresponding isolation transistors (not illustrated) are provided, which serve to decouple the sense amplifiers 5a, 5b, 5c, 5d during the reading out of the cells from that side that is not to be read out (i.e. to decouple either the cell field block 1a, 1b positioned at the left or that positioned at the right of the sense amplifiers 5a, 5b, 5c, 5d, or the corresponding bit lines 3a, 3b, respectively, from the respective sense amplifiers 5a, 5b, 5c, 5d).

As isolation transistors, corresponding NMOS-FETs may, for instance, be used, the source-drain-paths of which are adapted to interrupt the connection between the bit lines 3a, 3b and the respectively assigned sense amplifier 5a so as to decouple the corresponding side of the sense amplifier 5a from the bit lines 3a, 3b during the reading out and/or writing of the memory cells positioned at the respectively other side of the sense amplifier 5a.

The gate connections of the above-mentioned NMOS-FETs may be connected with each other and be respectively controlled jointly via a corresponding control voltage ISOL (in the case of the isolation transistors positioned at the left of the sense amplifier 5a) or a control voltage ISOR (in the case of the isolation transistors positioned at the right of the sense amplifier 5a).

The sense amplifiers 5a, 5b, 5c, 5d may, on principle, be any sense amplifiers used in prior art, e.g., sense amplifiers of the kind described in the book “VLSI Memory Chip Design” by Kiyoo Itoh, Publishing House Springer, Berlin, Heidelberg, New York, 2001 on pages 15-17, e.g., sense amplifiers having two NMOS-FETs and two PMOS-FETs (wherein the NMOS-FETs and PMOS-FETs may be interconnected in the type of a flip-flop), etc., etc.

As results further from FIG. 1, the sense amplifiers 5a, 5b, 5c, 5d may be connected with corresponding LDQ lines 11a, 11b via corresponding bit line switches 10a, 10b, 10c, 10d (CSL gates) (more exactly: a first, further sense amplifier signal input/output 8 of the sense amplifiers 5a, 5b, 5c, 5d with a respective first LDQ line 11a of a LDQ line pair 11, and a second, further, complementary sense amplifier signal input/output 9 of the sense amplifiers 5a, 5b, 5c, 5d with a respective second, complementary LDQ line 11b of the LDQ line pair 11).

Each bit line switch 10a, 10b, 10c, 10d (CSL gate) may—as illustrated in FIG. 1—comprise, for instance, two corresponding NMOS-FETs, the source-drain-paths of which electroconductively connect—in a conductive state of the bit line switch 10a, 10b, 10c, 10d—the LDQ line 11a and the first, further sense amplifier signal input/output 8 or the complementary LDQ line 11b and the second, further, complementary sense amplifier signal input/output 9, respectively (and, in a non-conductive state of the bit line switch 10a, 10b, 10c, 10d, electrically isolate or decouple, respectively, the LDQ lines 11a, 11b from the further sense amplifier signal inputs/outputs 8, 9).

The gate connections of the NMOS-FETs of the respective bit line switches 10a, 10b, 10c, 10d are connected with each other and are each jointly connected to a corresponding bit line control line 12a, 12b, 12c, 12d.

As will be explained in more detail in the following, the bit line control lines 12a, 12b, 12c, 12d are connected to a bit line decoder (or to respective output stages 13a, 13b, 13c, 13d of the bit line decoder, respectively).

Depending on a control signal CSL0, CSL1, CSL2, CSL3 respectively applied by the respective bit line decoder output stage 13a, 13b, 13c, 13d at the respective bit line control line 12a, 12b, 12c, 12d, the respective bit line switch 10a, 10b, 10c, 10d (or more exactly: the NMOS-FETs of the respective bit line switch 10a, 10b, 10c, 10d) can—as will be explained in more detail in the following—be placed in a conductive (or more exactly: in a respective one of a plurality of differently strongly conductive (cf. below)), or in a non-conductive state.

As results further from FIG. 1, the LDQ lines 11a, 11b can be connected with corresponding MDQ lines 15a, 15b via a corresponding MDQ switch 14 (more exactly: the first LDQ line 11a of the LDQ line pair 11 with a first MDQ line 15a of a MDQ line pair 15, and the second, complementary LDQ line 11b with a second, complementary MDQ line 15b of the MDQ line pair 15).

The MDQ switch 14 can—as is illustrated in FIG. 1—e.g., include two corresponding NMOS-FETs whose source-drain-paths connect—in a conductive state of the MDQ switch 14—the first LDQ line 11a and the first MDQ line 15a, or the second, complementary LDQ line 11b and the second, complementary MDQ line 15b in an electrically conductive manner (and, in a non-conductive state of the MDQ switch 14, electrically isolate or decouple the LDQ lines 11a, 11b from the MDQ lines 15a, 15b).

The gate connections of the NMOS-FETs of the MDQ switch 14 are connected with each other and are each jointly connected to a corresponding MDQ switch control line 16.

Depending on a control signal that is present at the MDQ switch control line 16, the MDQ switch 14 (or more exactly: the NMOS-FETs of the MDQ switch 14) may be placed in a conductive or in a non-conductive state.

The MDQ lines 15a, 15b are connected to a further sense amplifier 17 (here: to a secondary sense amplifier—SSA).

The first MDQ line 15a is connected with a first sense amplifier signal input/output of the further sense amplifier 17, and the second, complementary MDQ line 15b with a second, complementary sense amplifier signal input/output of the further sense amplifier 17.

Corresponding further signal inputs/outputs 18 of the further sense amplifier may—as is illustrated schematically in FIG. 1—be connected to corresponding external data connections (DQ pads or pins) of the DRAM.

The reading out of a corresponding memory cell (“read procedure”) may be initiated in that word line signals that are present at a corresponding word line 2 connect through the access transistors that are connected with the respective memory capacitors.

Each word line 2 is assigned to a particular cell field block 1a of the above-mentioned cell field blocks 1a, 1b and provides on its activation for the evaluation of all bit lines 3a, 3b of the cell field block 1a, 1b assigned to the word line 2 by the corresponding sense amplifiers 5a, 5b, 5c, 5d.

By means of a bit line address forwarded to the DRAM, a respective one of the sense amplifiers 5a, 5b, 5c, 5d arranged in the corresponding sense amplifier strip 4 is selected in that the bit line switch 10a, 10b, 10c, 10d (e.g., the bit line switch 10a) assigned to the selected sense amplifier 5a, 5b, 5c, 5d (e.g., the sense amplifier 5a) is placed from a non-conductive, closed state in a conductive, i.e. opened state (here: in one of a plurality of possible, differently widely open or differently strongly conductive states, cf. below).

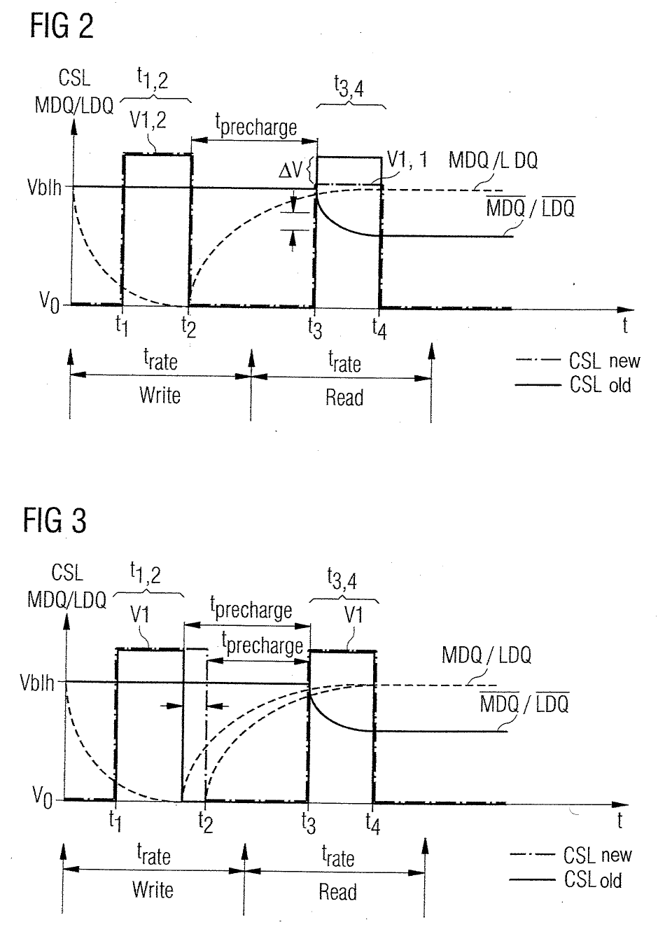

To this end—as is illustrated by way of example in FIG. 2—the control signal CSL0, CSL1, CSL2, CSL3 (e.g., the control signal CSL0) that is present at the bit line control line 12a, 12b, 12c, 12d assigned to the respective bit line switch 10a, 10b, 10c, 10d (e.g., the bit line switch 10a)—caused by the respective bit line decoder output stage 13a, 13b, 13c, 13d (e.g., the bit line decoder output stage 13a)—changes from a first (e.g., logic low) state, i.e., for instance, a first voltage intensity V₀, to a second, e.g., logic high state (of several possible, different logic high states (cf. below)), i.e., for instance, to a second voltage intensity V_{1,1}.

Then, the potential difference amplified by the selected sense amplifier 5a, 5b, 5c, 5d (e.g., the sense amplifier 5a) and present at the respective bit line sections is, via the corresponding bit line switch 10a, 10b, 10c, 10d (e.g., the bit line switch 10a), transmitted to the above-mentioned LDQ lines 11a, 11b, and then, via the MDQ switch 14 that has been placed in an opened, conductive state by means of a corresponding control signal applied to the MDQ switch control line 16, to the MDQ lines 15a, 15b and to the further sense amplifier 17 (secondary sense amplifier—SSA).

This sense amplifier evaluates the received signal and transmits a—correspondingly amplified—signal to the external data connections (DQ pads or pins) of the DRAM via the signal inputs/outputs 18.

Vice versa, during the reading or writing of data into the DRAM (“write procedure” (WRITE)), a signal present at the above-mentioned external data connections (DQ pads or pins) is correspondingly amplified by the above-mentioned further sense amplifier 17 (secondary sense amplifier—SSA) and transmitted, via the MDQ lines 15a, 15b and via the MDQ switch 14 that has been placed in an opened, conductive state by means of a corresponding control signal applied to the MDQ switch control line 16, to the LDQ lines 11a, 11b and to a sense amplifier 5a, 5b, 5c, 5d (e.g., the sense amplifier 5a) selected by a corresponding bit line address.

The selection of the corresponding sense amplifier 5a, 5b, 5c, 5d (e.g., the sense amplifier 5a) is—again—performed in that the bit line switch 10a, 10b, 10c, 10d (e.g., the bit line switch 10a) assigned to the selected sense amplifier 5a, 5b, 5c, 5d (e.g., the sense amplifier 5a) is placed from a non-conductive, closed state in a conductive, i.e. opened state (here: in a differently widely open or differently strongly conductive state as compared to the “read procedure” (READ), in particular in a wider open or more strongly conductive, lower-resistive state as compared to the “read procedure” (READ), cf. below).

To this end—as is also illustrated by way of example in FIG. 2—the control signal CSL0, CSL1, CSL2, CSL3 (e.g., the control signal CSL0) present at the bit line control line 12a, 12b, 12c, 12d (e.g., the bit line control line 12a) assigned to the respective bit line switch 10a, 10b, 10c, 10d (e.g., the bit line switch 10a) changes—caused by the respective bit line decoder output stage 13a, 13b, 13c, 13d (e.g., the bit line decoder output stage 13a)—from the above-mentioned first (e.g., logic low) state, i.e., for instance, the first voltage intensity V₀, to a third, e.g., logic high state that differs from the above-mentioned second (logic high) state, i.e., for instance, to a third voltage intensity V_{1,2} that differs from the first and second voltage intensities V₀, V_{1,1} (in particular to a voltage intensity V_{1,2} that is larger than the above-mentioned voltage intensity V_{1,1} used during the “read procedure” (READ).

The opened bit line switch 10a, 10b, 10c, 10d (e.g., the bit line switch 10a) switches the signal amplified by the SSA to the selected sense amplifier 5a, 5b, 5c, 5d (e.g., the sense amplifier 5a) that has already been amplified with the predecessor data of the cell, which can then write the corresponding data into the respective memory cell.

For the possibly required overwriting of the predecessor data in the respectively selected sense amplifier 5a, 5b, 5c, 5d (e.g., the sense amplifier 5a) by the signal sent by the further sense amplifier 17 during the “write procedure” (WRITE), the bit line switch 10a, 10b, 10c, 10d (e.g., the bit line switch 10a) assigned to the selected sense amplifier 5a, 5b, 5c, 5d (e.g., the sense amplifier 5a) should be as lowly resistive as possible.

For this reason, during the “write procedure” (WRITE)—as mentioned above—the bit line switch 10a, 10b, 10c, 10d (e.g., the bit line switch 10a) assigned to the respectively selected sense amplifier 5a, 5b, 5c, 5d (e.g., the sense amplifier 5a) is placed in a more strongly conductive or wider open state than during the “read procedure” (READ).

On the other hand, in the above-described—inverse—case of the reading out of data (“read procedure” (READ)) it must be ensured that the LDQ and MDQ lines 11a, 11b, 15a, 15b that have been brought to a predefined potential—e.g., by means of an EQL control 19—do not influence the respectively selected sense amplifier 5a, 5b, 5c, 5d (e.g., the sense amplifier 5a) to such an extent that the original cell information tilts.

For this case, the opened bit line switch 10a, 10b, 10c, 10d (e.g., the bit line switch 10a) assigned to the respectively selected sense amplifier 5a, 5b, 5c, 5d (e.g., the sense amplifier 5a) must not be too lowly resistive.

For this reason—as mentioned above—the bit line switch 10a, 10b, 10c, 10d (e.g., the bit line switch 10a) assigned to the respectively selected sense amplifier 5a, 5b, 5c, 5d (e.g., the sense amplifier 5a) is—during the “read procedure” (READ)—placed in a less strongly conductive or less open state than during the “write procedure” (WRITE).

To this end—as results from FIG. 2—the voltage intensity V_{1,1} of the control signal CSL0, CSL1, CSL2, CSL3 fed to the bit line control line 12a, 12b, 12c, 12d (e.g., the bit line control line 12a) of the respective bit line switch 10a, 10b, 10c, 10d (e.g., the bit line switch 10a) during the “read procedure” (READ) may, for instance, be by more than 5%, 10%, or 15% smaller (or e.g., by more than 20%, 25%, or 30% smaller) than the voltage intensity V_{1,2} of the control signal CSL0, CSL1, CSL2, CSL3 fed to the bit line control line 12a, 12b, 12c, 12d (e.g., the bit line control line 12a) of the respective bit line switch 10a, 10b, 10c, 10d (e.g., the bit line switch 10a) during the “write procedure” (WRITE).

The pulse length t_{1,2} of the control signal CSL0, CSL1, CSL2, CSL3 fed to the bit line control line 12a, 12b, 12c, 12d (e.g., the bit line control line 12a) of the respective bit line switch 10a, 10b, 10c, 10d (e.g., the bit line switch 10a) during the “write procedure” (WRITE) may—as is also illustrated in FIG. 2—be as large or substantially as large as the pulse length t_{3,4} of the control signal CSL0, CSL1, CSL2, CSL3 fed to the bit line control line 12a, 12b, 12c, 12d (e.g., the bit line control line 12a) of the respective bit line switch 10a, 10b, 10c, 10d (e.g., the bit line switch 10a) during the “read procedure” (READ).

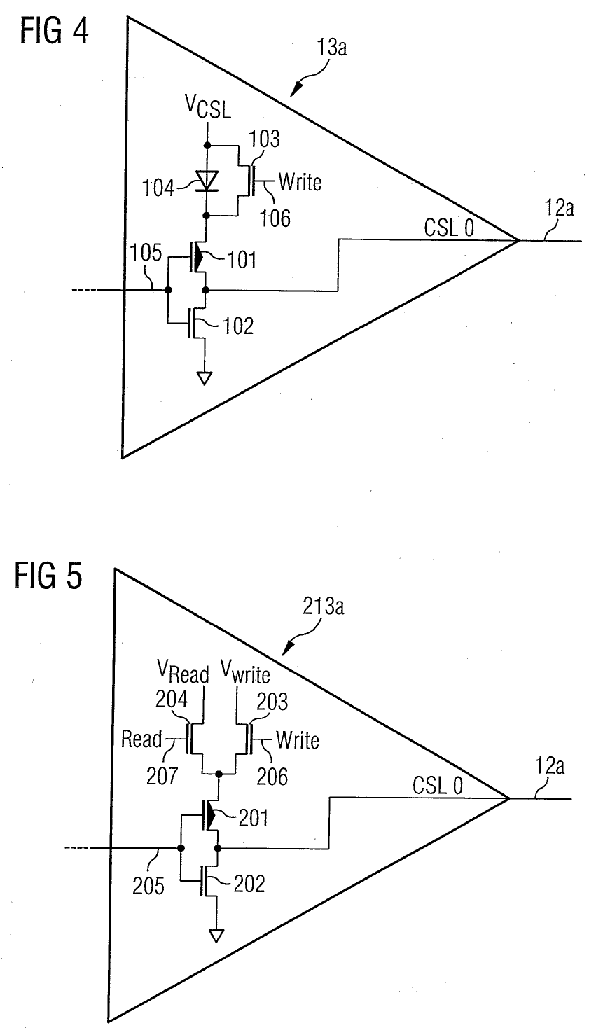

FIG. 4 illustrates a schematic detail representation of a first exemplary design of a bit line decoder output stage 13a that is adapted to be used in the DRAM according to FIG. 1 for achieving the different voltage intensities V_{1,1} and V_{1,2} of the bit line control signal CSL0, CSL1, CSL2, CSL3 during the “read procedure” (READ) and the “write procedure” (WRITE) (here: with the example of the bit line decoder output stage 13a connected with the bit line control line 12a of the bit line switch 10a).

The bit line decoder output stage 13a includes—correspondingly similar as conventional bit line decoder output stages—an inverter amplifier circuit with a NMOS-FET 102 and a PMOS-FET 101.

The gates of the NMOS-FET 102 and of the PMOS-FET 101 are connected with each other.

A corresponding control signal is fed to the gates of the NMOS-FET 102 and of the PMOS-FET 101 by the bit line decoder at a line 105.

The source-drain-path of the NMOS-FET 102 is connected to the ground as well as to the bit line control line 12a and the source-drain-path of the PMOS-FET 101.

The source-drain-path of the PMOS-FET 101 is—other than with conventional bit line decoder output stages—not connected directly to the supply voltage V_{CSL}, but to a diode 104 and to the source-drain-path of a (further) NMOS-FET 103 that is connected in series to the diode 104.

The diode 104 and the (further) NMOS-FET 103 are connected to the supply voltage V_{CSL}.

At the gate of the (further) NMOS-FET 103, a control signal (Write) is applied at a control line 16 during the above-mentioned “write procedure”.

The applying of the control signal (Write) to the control line 106 results in that the (further) NMOS-FET 103 is placed in a conductive state and thus bridges the diode 104.

The consequence is that the source-drain-path of the PMOS-FET 101 is conductively connected with the above-mentioned—relatively high—supply voltage V_{CSL} during the “write procedure”.

At the beginning of the “write procedure” (up to a point in time t₁, cf. FIG. 2), the gates of the NMOS-FET 102 and of the PMOS-FET 101 are fed with a logic high control signal at the line 105 by the bit line decoder, which results in that the NMOS-FET 102 is placed in a conductive state and the PMOS-FET 101 in a locked state.

The control signal CSL0 output at the bit line control line 12a then has the above-mentioned—logic low—first voltage intensity V₀ (cf. FIG. 2).

At the point in time t₁ (cf. FIG. 2) the control signal fed to the gates of the NMOS-FET 102 and of the PMOS-FET 101 by the bit line decoder at the line 105 changes to logic low, which results in that the NMOS-FET 102 is placed in a locked state and the PMOS-FET 101 in a conductive state.

The control signal CSL0 output at the bit line control line 12a then has the above-mentioned—relatively high—voltage intensity V_{1,2} (since the source-drain-path of the PMOS-FET 101 is conductively connected with the above-mentioned—relatively high—supply voltage V_{CSL} during the “write procedure”).

At the point in time t₂ (cf. FIG. 2) the control signal fed to the gates of the NMOS-FET 102 and of the PMOS-FET 101 by the bit line decoder at the line 105 changes back to logic high, which results in that the NMOS-FET 102 is placed back in a conductive state and the PMOS-FET 101 is placed back in a locked state.

The control signal CSL0 output at the bit line control line 12a then again has the—logic low—voltage intensity V₀ (cf. FIG. 2).

During the “read procedure”—other than during the “write procedure”—no control signal is applied at the gate of the (further) NMOS-FET 103; during the “read procedure” the (further) NMOS-FET 103 is thus in a locked state.

At the beginning of the “read procedure” (up to a point in time t₃, cf. FIG. 2) a logic high control signal is fed to the gates of the NMOS-FET 102 and of the PMOS-FET 101 by the bit line decoder at the line 105, which results in that the NMOS-FET 102 is placed in a conductive state and the PMOS-FET 101 in a locked state.

The control signal CSL0 output at the bit line control line 12 then has the above-mentioned—logic low—first voltage intensity V₀ (cf FIG. 2).

At the point in time t₃ (cf. FIG. 2) the control signal fed to the gates of the NMOS-FET 102 and of the PMOS-FET 101 by the bit line decoder at the line 105 changes to logic low, which results in that the NMOS-FET 102 is placed in a locked state and the PMOS-FET 101 is placed in a conductive state.

The control signal CSL0 output at the bit line control line 12 then has—as illustrated in FIG. 2—the above-mentioned voltage intensity V_{1,1} (reduced vis-à-vis the voltage intensity V_{1,2} occurring during the “write procedure” by the voltage drop ΔV at the diode 104) (since the source-drain-path of the PMOS-FET 101 is not connected directly conductively with the above-mentioned—relatively high—supply voltage V_{CSL} during the “read procedure”, but via the diode 104 that causes the voltage drop ΔV).

At the point in time t₄ (cf. FIG. 2) the control signal fed to the gates of the NMOS-FET 102 and of the PMOS-FET 101 by the bit line decoder at the line 105 changes back to logic high, which results in that the NMOS-FET 102 is placed back in a conductive state and the PMOS-FET 101 is placed back in a locked state.

The control signal CSL0 output at the bit line control line 12 then again has the—logic low—voltage intensity V₀ (cf. FIG. 2).

FIG. 5 illustrates a schematic detail representation of a second, alternative exemplary design of a bit line decoder output stage 213a that is adapted to be used in a DRAM according to FIG. 1 for achieving the different voltage intensities V_{1,1} and V_{1,2} of the bit line control signal CSL0, CSL1, CSL2, CSL3 during the “read procedure” (READ) and the “write procedure” (WRITE).

The bit line decoder output stage 213a illustrated in FIG. 5 includes—correspondingly similar as conventional bit line decoder output stages—an inverter amplifier circuit with a NMOS-FET 202 and a PMOS-FET 201.

The gates of the NMOS-FET 202 and of the PMOS-FET 201 are connected with each other.

The gates of the NMOS-FET 202 and of the PMOS-FET 201 are fed with a corresponding control signal by the corresponding bit line decoder at a line 205.

The source-drain-path of the NMOS-FET 202 is connected to the ground as well as to the bit line control line 12a and the source-drain-path of the PMOS-FET 201.

The source-drain-path of the PMOS-FET 201 is not connected directly to the supply voltage V_{CSL}, but to the source-drain-path of a NMOS-FET 204 and to the source-drain-path of a NMOS-FET 203 that is connected in series to the NMOS-FET 204.

The NMOS-FET 203 is connected to a—relatively high—supply voltage V_{Write}, and the NMOS-FET 204 to a—relatively low—supply voltage V_{Read} (in particular to a supply voltage V_{Read} that is lower than the supply voltage V_{Write}).

A control signal (Write) is applied to the gate of the NMOS-FET 203 at a control line 206 during the above-mentioned “write procedure”, not, however, during the “read procedure”.

This results in that the NMOS-FET 203 is placed in a conductive state during the “write procedure” and in a locked state during the “read procedure”.

Contrary to this, a control signal (Read) is applied at the gate of the NMOS-FET 204 at a control line 207 during the above-mentioned “read procedure”, not, however, during the “write procedure”

This results in that the NMOS-FET 204 is placed in a conductive state during the “read procedure” and in a locked state during the “write procedure”.

The consequence of this is that the source-drain-path of the PMOS-FET 201 is connected with the above-mentioned—relatively high—supply voltage V_{Write} during the “write procedure”, and during the “read procedure” with the above-mentioned—relatively low—supply voltage V_{Read}.

The signals fed to the gates of the NMOS-FET 202 and of the PMOS-FET by the bit line decoder at the line 205 correspond to the signals explained with respect to FIG. 4 and applied at the line 105 of the bit line decoder output stage 13a during the “write procedure” and the “read procedure”.

In correspondence with the bit line decoder output stage 13a illustrated in FIG. 4, there is, also with the bit line decoder output stage 213a illustrated in FIG. 5, output a control signal CSL0 including the above-mentioned—relatively high—voltage intensity V_{1,2} at the bit line control line 12a during the “write procedure” (since the source-drain-path of the PMOS-FET 201 is conductively connected with the above-mentioned—relatively high—supply voltage V_{Write} during the “write procedure”), and, during the “read procedure”, a control signal CSL0 including the above-mentioned—relatively low—voltage intensity V_{1,1} (since the source-drain-path of the PMOS-FET 201 is conductively connected with the above-mentioned—relatively low—supply voltage V_{Read} during the “read procedure”).

As is illustrated in FIG. 3, in an embodiment of a DRAM which is alternative to the embodiment illustrated in FIG. 1 and FIG. 4 or FIG. 5, respectively—with an otherwise identical structure as illustrated in FIG. 1—the pulse length t_{1,2} of a control signal CSL0, CSL1, CSL2, CSL3 fed to the bit line control line 12a, 12b, 12c, 12d (e.g., the bit line control line 12a) of the respective bit line switch 10a, 10b, 10c, 10d (e.g., the bit line switch 10a) during the “write procedure” (WRITE) may be larger than the pulse length t_{3,4} of a control signal CSL0, CSL1, CSL2, CSL3 fed to the bit line control line 12a, 12b, 12c, 12d (e.g., the bit line control line 12a) of the respective bit line switch 10a, 10b, 10c, 10d (e.g., the bit line switch 10a) during the “read procedure” (READ).

For instance, during the “write procedure” (WRITE), the pulse length t_{1,2} of the control signal CSL0, CSL1, CSL2, CSL3 (i.e. the duration for which the control signal CSL0, CSL1, CSL2, CSL3 is “logic high” or the assigned bit line switch 10a, 10b, 10c, 10d (e.g., the bit line switch 10a) is in a conductive, i.e. opened state) may be by more than 5%, 10%, or 15% larger (or e.g., by more than 20%, 30%, or 40% larger) than the pulse length t_{3,4} of the control signal CSL0, CSL1, CSL2, CSL3 during the “read procedure” (READ).

The voltage intensity V₁ of the control signal CSL0, CSL1, CSL2, CSL3 during the “logic high” signal state may—as is illustrated by way of example in FIG. 3 (and other than with the embodiment explained by means of FIG. 1 and FIG. 4 or FIG. 5, respectively)—be equal or substantially equal during the “write procedure” (WRITE) and the “read procedure” (READ).

As bit line decoder output stage there may then—instead of the bit line decoder output stages 13a, 213a illustrated in FIG. 4 and FIG. 5—be used a conventional bit line decoder output stage (with an inverter amplifier circuit including, e.g., a NMOS-FET 102 and a PMOS-FET 101 as illustrated in FIG. 4, but without a diode 104 and without a—further—NMOS-FET 103).

Alternatively—correspondingly similar as explained above with reference to FIGS. 1, 4, and 5—in addition to control signal pulse lengths t_{1,2} or t_{3,4} which are respectively selected to be differently long and which are correspondingly illustrated in FIG. 3, the voltage intensity of the control signal CSL0, CSL1, CSL2, CSL3 may, during the “write procedure” (WRITE) and the “read procedure” (READ), with the “logic high” signal state during the “write procedure” (WRITE)—correspondingly similar as illustrated in FIG. 2—be higher than during the “read procedure” (READ) (e.g., by more than 5%, 10%, 15%, 20%, 25%, or 30% higher, with e.g., by more than 5%, 10%, 15%, 20%, 30%, or 40% differently large pulse lengths t_{1,2} or t_{3,4}, etc., etc.).

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor memory comprising:
at least one sense amplifier; and
a device for switching the sense amplifier to or off at least one line, wherein the device is, during the switching of the sense amplifier to the line, placed for a differently long time and/or differently strongly in a conductive state, depending on the respective operating mode.

2. The semiconductor memory according to claim 1, wherein the operating mode may be a read mode.

3. The semiconductor memory according to claim 1, comprising wherein the operating mode may be a write mode.

4. The semiconductor memory according to claim 1, wherein the device is a bit line switch.

5. The semiconductor memory according to claim 4, comprising wherein the bit line switch comprises a transistor.

6. The semiconductor memory according to claim 5, comprising wherein the transistor is, depending on the respective operating mode of the semiconductor memory, placed from a non-conductive state in a conductive state for a differently long time and/or differently strongly, and then back to the non-conductive state.

7. The semiconductor memory according to claim 1, comprising wherein a control signal is fed to a control input of the transistor for a differently long time, depending on the respective operating mode of the semiconductor memory.

8. The semiconductor memory according to claim 1, comprising wherein a respective control signal with a respectively different voltage intensity is fed to a control input of the transistor depending on the respective operating mode of the semiconductor memory.

9. The semiconductor memory according to claim 1, comprising wherein, during the switching of the sense amplifier to the line, the sense amplifier is connected with a further sense amplifier via the line.

10. The semiconductor memory according to claim 1, comprising wherein the sense amplifier is a primary sense amplifier.

11. The semiconductor memory according to any of claims 9, wherein the further sense amplifier is a secondary sense amplifier.

12. The semiconductor memory according to claim 1, comprising where the semiconductor memory is a DRAM.

13. A DRAM memory comprising:
a DRAM memory cell;
at least one sense amplifier; and
a device for switching the sense amplifier to or off at least one line, wherein the device is, during the switching of the sense amplifier to the line, placed for a differently long time and/or differently strongly in a conductive state, depending on the respective operating mode.

14. The memory according to claim 13, wherein the operating mode may be a read mode or a write mode.

15. The semiconductor memory according to claim 13, wherein the device is a bit line switch.

16. The semiconductor memory according to claim 15, comprising wherein the bit line switch comprises a transistor.

17. The semiconductor memory according to claim 16, comprising wherein the transistor is, depending on the respective operating mode of the semiconductor memory, placed from a non-conductive state in a conductive state for a differently long time and/or differently strongly, and then back to the non-conductive state.

18. The semiconductor memory according to claim 17, comprising wherein a control signal is fed to a control input of the transistor for a differently long time, depending on the respective operating mode of the semiconductor memory.

19. The semiconductor memory according to claim 18, comprising wherein a respective control signal with a respectively different voltage intensity is fed to a control input of the transistor depending on the respective operating mode of the semiconductor memory.

20. The semiconductor memory according to claim 19, comprising wherein, during the switching of the sense amplifier to the line, the sense amplifier is connected with a further sense amplifier via the line.

21. A method for operating a semiconductor memory comprising:
providing at least one sense amplifier and a device for switching the sense amplifier to or off at least one line; and
switching the device in a conductive state for switching the sense amplifier to the line, wherein the device is switched in a conductive state for a differently long time and/or differently strongly, depending on the respective operating mode of the semiconductor memory.

22. A semiconductor memory comprising:
at least one sense amplifier; and
means for switching the sense amplifier to or off at least one line, wherein the switch means is, during the switching of the sense amplifier to the line, placed for a differently long time and/or differently strongly in a conductive state, depending on the respective operating mode.
